(19) United States
(12) Patent Application Publication
(10) Pub. No.: US 2015/0013461 A1
(43) Pub. Date: Jan. 15, 2015

(54) DEVICE AND METHOD FOR MEASURING PHYSICAL PARAMETERS USING SAW SENSORS

(71) Applicant: ENVIRONETIX TECHNOLOGIES CORP., Orono, ME (US)

(72) Inventors: THOMAS POLLARD, ORONO, ME (US); DONALD McCANN, ORONO, ME (US)

(21) Appl. No.: 14/330,979

(22) Filed: Jul. 14, 2014

Related U.S. Application Data
(60) Provisional application No. 61/845,706, filed on Jul. 12, 2013.

(51) Int. Cl. H01L 41/113; G01H 11/08

(52) U.S. Cl. CPC H01L 41/1132; G01H 11/08
USPC 73/579; 310/313 A

(57) ABSTRACT

A SAW mode sensor for sensing parameters such as temperature, pressure, and strain. The sensor is made of a piezoelectric crystal cut at selected angles, with an attached electrode layer with a signal receiver and signal transmitter. The signal receiver initiates a wave in the substrate which propagates in the substrate and the speed of the wave and amplitude of the wave is interpreted as the parameter being sensed.

### TECHNICAL FIELD

The disclosed technology generally relates to sensors, and more particularly to surface acoustic wave sensors for harsh environments.

### BACKGROUND

Microwave acoustic sensors rely on acoustic wave technology where acoustic wave modes are excited and detected in an environmentally sensitive substrate using integrated electromechanical transducer(s). Among the acoustic wave modes that can be used for sensing—e.g. bulk acoustic wave (BAW), film bulk acoustic resonators (FBAR), acoustic plate modes (APM), and surface acoustic waves (SAW)—the SAW offers the greatest flexibility for direct implementation of distinct filtering and sensing applications as the fabrication process is comparatively simple (typically only one metallic layer patterning process is required), the devices exhibit low propagation loss (wave is guided by the surface) permitting long signal delays in a relative small area, and the ability to manipulate the mode propagation path in a complex manner via proper design patterned electrode geometries at the surface.

Excitation and detection of SAW modes rely on the use of piezoelectric crystal substrates with metallic transducers located at the surface. A material is said to be piezoelectric if upon application of a mechanical force the body becomes electrically polarized (direct effect), and conversely upon application of an electric field the body becomes mechanically deformed (inverse effect). These devices have interdigital transducer(s) (IDTs) affixed to the substrate surface that make use of the piezoelectric effect to excite and detect the supported SAW in the substrate. These structures typically consist of periodic parallel electrodes having a ½ or ¼ of a wavelength repetition rate extending 5-200 wavelengths in length which are electrically connected to achieve the desired polarity. The IDT electrodes are usually much longer (typically 5-200 times longer than a wavelength) along the aperture dimension (normal to propagation direction) to reduce diffraction effects (wave-front spreading with distance) for the excited SAW. IDT(s) are most efficient at SAW excitation/detection at a particular frequency (namely, SAW velocity/IDT wavelength) as the entire structure works constructively due to the periodicity of the electrode electric surface potential forced by the IDT geometry. Other similar periodic electrode structures are sometimes employed in device design that act as Bragg reflectors (displaying a finite frequency band(s) where energy is efficiently reflected back towards source) and consist of arrays of periodic open or short-circuited electrodes having a ½ wavelength repetition rate that typically extend 10-500 wavelengths.

Two of the most common SAW device topologies used for both sensing and non-sensing applications are delay-lines and resonators. A typical delay-line device has two IDTs spaced some distance apart where one IDT is used to launch the SAW and the other is used to detect the SAW after traveling across the delay region. Comparison of the IDT electrical signals allows the delay through the device to be measured, which is approximately IDT center-to-center distance divided by the SAW velocity. A typical resonator configuration makes use of one IDT to excite/detect the SAW mode and a pair of Bragg reflectors placed along each side of the transducer to contain the majority of energy within the cavity. With this layout very high quality factor (Q) resonators can be realized with fundamental resonance frequency approximately given by SAW velocity divided by the IDT wavelength.

For sensing applications, SAW devices are designed so that delay times, resonant frequencies and relative signal levels are sensitive to environmental conditions such as temperature, pressure, applied strain, etc. In general changes in the device environment affect parameters that alter device response: the SAW velocity and attenuation rate (e.g. material constants change with temperature), and the dimensions along the propagation path (e.g. resulting from thermal expansion or applied strain). Using calibration curves and extracted delay times, or resonance frequencies and/or signal levels, the measurand of interest can be determined.

The chosen orientation of the substrate from a bulk piezoelectric crystal and the SAW propagation direction along the surface can be tailored to more effectively react to particular measurands. In addition, device packaging can also increase or decrease sensitivity to a certain measurand. The overall sensor performance is determined by the piezoelectric crystal material, crystallographic orientation of the cut substrate, propagation direction along the surface, and the patterned electrode geometry.

A key factor in the performance of the sensor is the orientation (with respect to the crystalline principal axis) or “cut” of the crystalline material used to fabricate the sensor. Surface wave velocities are determined by the cut of a given crystal and relative propagation direction, and by the extent of change in the surface wave velocity induced by changes in ambient conditions (temperature, pressure, etc.). Thus, for a temperature sensor it is desirable for the given substrate material, cut, and propagation direction to exhibit a high degree of SAW sensitivity to temperature changes over the temperature range of interest and a low sensitivity to other conditions such as pressure. It should be noted that since most SAW devices are used as filters and oscillators in electronics devices where low temperature sensitivity is optimal, most patented orientations of LGX exhibit “temperature compensation around room temperature”—i.e. the SAW device delay or resonance frequency changes very little with changes in temperature around room temperature.

Conventional SAW piezoelectric substrates cannot withstand rapid thermal shock or prolonged exposure to temperatures above 600° C. due to crystal phase transitions, thermal shock cracking, or accelerated crystal decomposition and degradation. Furthermore, currently identified orientations for high temperature SAW crystals suffer from insufficient temperature sensitivity over large temperature ranges, e.g. 0° C.-1,000° C., needed for reliable temperature sensing in harsh environments. Many prior art SAW device designs in fact seek temperature insensitivity (temperature compensation) throughout the desired operational temperature range for the intended application—e.g. radio-frequency filters and reference resonators. Newer piezoelectric crystals from the Langasite family of crystals (LGX), including Langasite (LGS) and Langatate (LGT), can be operated near their melting points (˜1470° C. for LGS), but prior art or commercially available substrates are cut to crystallographic orientations with useful propagation directions that are temperature compensated around room temperature and typically display insufficient temperature sensitivity below 150° C. However, the use of alternative substrate cuts and propagation directions with these materials can allow increased temperature sensitivity due to the anisotropic nature of the crystalline substrates employed, and at the same time still display attractive features such as moderate to high piezoelectric coupling, low power flow angle, and low diffraction to achieve a greater sensor operational temperature range (<0° C.-1,000° C.). Thus crystallographic orientations and propagation directions on piezoelectric LGS and LGT are desired that offer improved sensor characteristics for specific applications, such as temperature, pressure, torque, strain and others.

The use in prior art of SAW sensing devices for measuring parameters such as pressure, torque, strain and others also has not fully solved the problem of accurate extraction of parameters of interest from a SAW device as a function of the measurands. Of particular significance is the ability to first accurately measure temperature, in order to subsequently determine other parameters of interest, including static and dynamic strain amplitudes, as the relationships between the SAW device response and measurands are typically temperature dependent.

From prior art, excitation of the SAW device and collection and processing of the device response to obtain the state of the sensor (e.g. the device resonance frequency or delay-time) requires a finite amount of time (maximum interrogation rate), which can be greater than the two times the period of dynamic measurand variations (e.g. dynamic strain of a vibrating part). For these cases such conditions lead to the problem of under-sampling the state of the sensor, which upon subsequent spectral analysis of the sensor state over time results in non-unique determination of dynamic measurand frequencies as a result of aliasing effects. The obvious solution is to sample faster, but for many applications this solutions becomes too expensive and increases complexity of the electronics and its configuration, as the amount of parallel running hardware required and the speed at which it operates increases.

The commercial need for health-monitoring sensing components in aerospace, power-generation, oil, etc. industries is well-established. Temperature, strain, pressure and other sensors that operate from ambient to high temperatures and in harsh environments are needed in many application areas such as internal combustion engine measurement (in-cylinder pressure, exhaust, and so on), oil, gas and geothermal explorations and drilling, gas turbines and utility application (boilers, life safety, and so forth). In many cases the required high operating temperatures (above 300° C.) and the presence of corrosive media may impose drastic limitations on the sensor materials. For instance, commercially available silicon piezoresistive pressure sensors are often unable to work at such high temperatures and reliably measuring in situ parameters of interest on rotating parts in harsh environments, e.g. turbine blades in or near the hot section of a jet engine or gas turbine, poses additional challenges. While state-of-the-art efforts rely on wired sensing solutions, SAW-based technologies offer a cost-effective, wireless alternative where the above-mentioned limitations to current SAW sensing devices are removed.

### SUMMARY OF THE DISCLOSURE

The disclosed technology includes surface acoustic wave (SAW) sensors using Langasite-family crystals (LGX) and are suitable for use as temperature, static and/or dynamic strain, torque, pressure or other applicable sensors in a number of embodiments for a variety of high-temperature, high-pressure, high g-force, and/or corrosive harsh-environment operational settings. Such sensors can be passive and wireless, being powered by periodic RF signals received at one or more antennas.

The novel features of the disclosed technology include sensors and strain-sensitive devices to be used in simultaneously high-temperature, high-pressure, high-g-force, corrosive or other harsh operational environments, e.g. within a gas turbine engine. Such features include those listed below:
1. The crystallographic orientation of the piezoelectric substrate material (for harsh environment applications the material composing the SAW sensing substrate must survive and retain its piezoelectricity at high temperatures. All LGX crystals operate at temperatures up to their melting points (˜1470° C. for LGS) without losing piezoelectric properties).
2. The responsiveness of the sensor to desired measurands.
3. The ability to devise an apparatus that can transmit measurands to the sensing device with minimal interference.
4. The ability to wirelessly communicate data from sensing devices to an external transceiver.
5. The ability of the sensor to operate battery-free in situ.
6. The ability for signal processing to support accurate extraction of desired measurand from spectral data in real time.

The disclosed technology includes a sensor which can be passive and wireless, and that provides information for calculating temperature, strain, and other measurands in an accurate manner. A particularly unique feature of the disclosed technology is its ability to provide sensing measurements reliably in a variety of harsh and hostile environments. The disclosed technology provides in situ measurements of parameters of extreme interest to original equipment manufacturers in a variety of industries, including aerospace, power generation and oil production. Additionally, the disclosed technology advances efforts to produce commercial health monitoring systems for entities (such as power plants) and components.

### BRIEF DESCRIPTION OF THE DRAWINGS

FIG. 1 shows a perspective view of a sensor of the disclosed technology.

FIG. 2 shows a perspective view of a sensor of the disclosed technology.

FIG. 3 shows a perspective view of a sensor of the disclosed technology.

FIG. 4 shows a coordinate system in space with an X, Y, and Z plane.

FIG. 5 shows a plane set at a selected Euler angle to illustrate the plane on which a crystal is cut.

FIG. 6 shows a plane set at a selected Euler angle to illustrate the plane on which a crystal is cut.

FIG. 7 shows a crystal with hexagonal crystallographic axes projected onto on quartz crystal.

FIG. 8 shows a plane for cutting the crystal of FIG. 6 on a selected Euler angle.

FIG. 9 shows a perspective view of a sensor pair of the disclosed technology.

FIG. 10 shows a perspective view of a sensor pair of the disclosed technology.

FIG. 11 shows a perspective view of a sensor pair of the disclosed technology.

FIG. 12 shows a method in accordance with the disclosed technology.

FIG. 13 shows a table of Euler Angles for defining a cut angle of a piezoelectric crystal in accordance with the disclosed technology.

### DESCRIPTION OF PREFERRED EMBODIMENTS

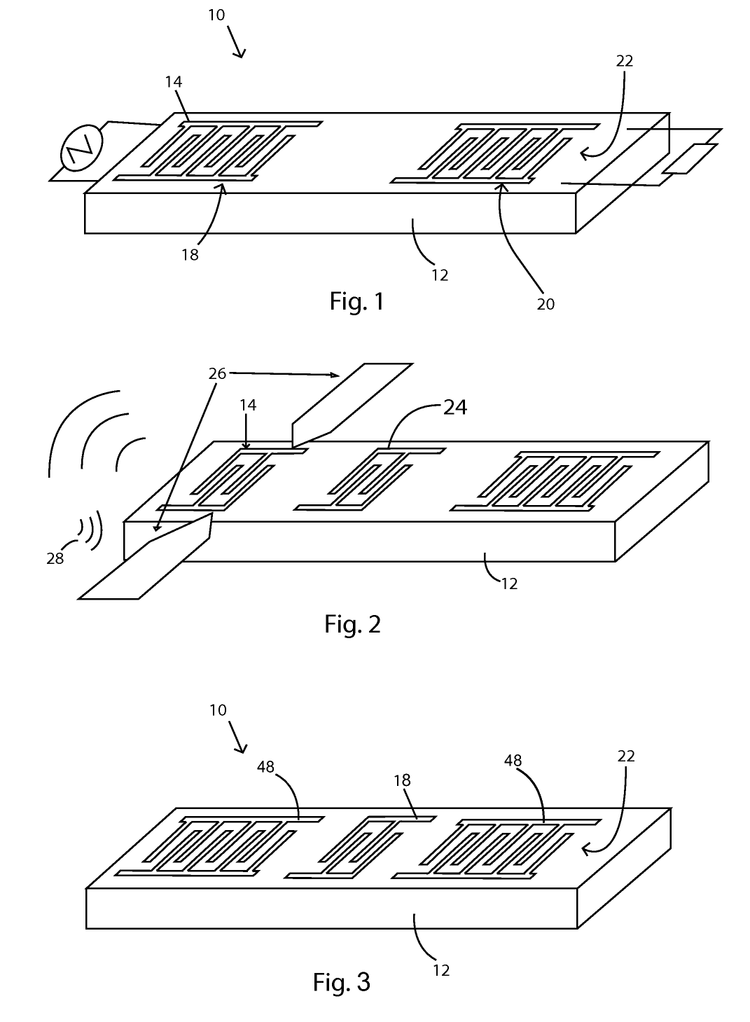

As shown in FIG. 1, the device 10 includes a piezoelectric crystal 12 on which is affixed a layer of metallic electrodes 22. The input 18 and output 20 structure each consists of a periodic interdigitated transducer (IDT) 14 electrode structure of several wavelength periodicities, λ, in width. The synchronous operation of the IDT at the surface launches an electromechanical surface acoustic wave (SAW) which propagates at ˜3×10³ m/s, or approximately five orders of magnitude slower than the propagation of the electromagnetic wave (EM) in vacuum (3×10⁸ m/s). This allows significant delay from input to output, namely five orders of magnitude longer delay than for an EM wave propagating in air using a similar sized structure. For this reason, the device using the IDT geometry shown in FIG. 1 is called a delay line, and represents one of many possible signal processing devices enabled by SAW technology. These devices are very small, ranging from a few millimeters to sub-millimeters in length depending on the frequency of operation (typically between a few MHz to several GHz). Power is applied to the device FIG. 1 with a direct wired connection to a radio frequency (RF) source powered by battery or a power outlet.

A sensor of the disclosed technology could be various sizes and configurations. A typical configuration for a device as shown in FIG. 1 would be one in which the piezoelectric crystal 10 is approximately 4.5 mm long, 2 mm wide, and 0.5 mm tall. In the example shown in FIG. 1, the layer of metallic electrodes 22 could be 100 nm thick, 2 um wide and 400 um long. This layer of metallic electrodes is affixed to the piezoelectric crystal 12 by means of an adhesive layer such as Cr, or Zr, or W. What is sensed in the device of FIG. 1 is the time delay in the speed of a wave traveling from the input structure 18 to the output structure 20. The speed of this wave is determined by the physical condition of the piezoelectric crystal, such as its temperature or strain. The piezoelectric crystal is calibrated so that temperature, strain or pressure can be calculated from the speed of the wave propagating through the piezoelectric crystal structure.

Another embodiment of the disclosed technology is shown in FIG. 2. This embodiment is a wireless surface acoustic wave sensor which incorporates a SAW delay line 24 in a design that also includes an antenna(s) 26 connected to an IDT 14, offering a SAW device configuration permitting wireless sensor interrogation. The sensor of this design can be powered only by an applied radio frequency (RF) interrogating signal 28 that is received by the sensor antenna(s) 26. The applied RF signal 28 is converted to an electromechanical signal via the IDT(s) 14, which propagates within the piezoelectric substrate 12. Any change in the sensing measurand (temperature, pressure, etc.) changes the properties (speed and amplitude) of the signal, and the modified signal is retransmitted wirelessly via the IDT 14 and antenna 26, which is then detected by a signal processing system. Such passive operation eliminates the need for batteries or other external power sources attached to the sensor, which typically cannot operate in harsh environments. In addition, the passive wireless approach simplifies how sensors are attached to non-stationary or rotating parts by removal of sliding mechanical contacts such as slip-rings. Furthermore, SAW sensor technology supports device coding, which permits multiple sensor wireless interrogation—an important feature allowing temperature, pressure, or other measurands to be extracted from multiple locations by a single interrogation unit.

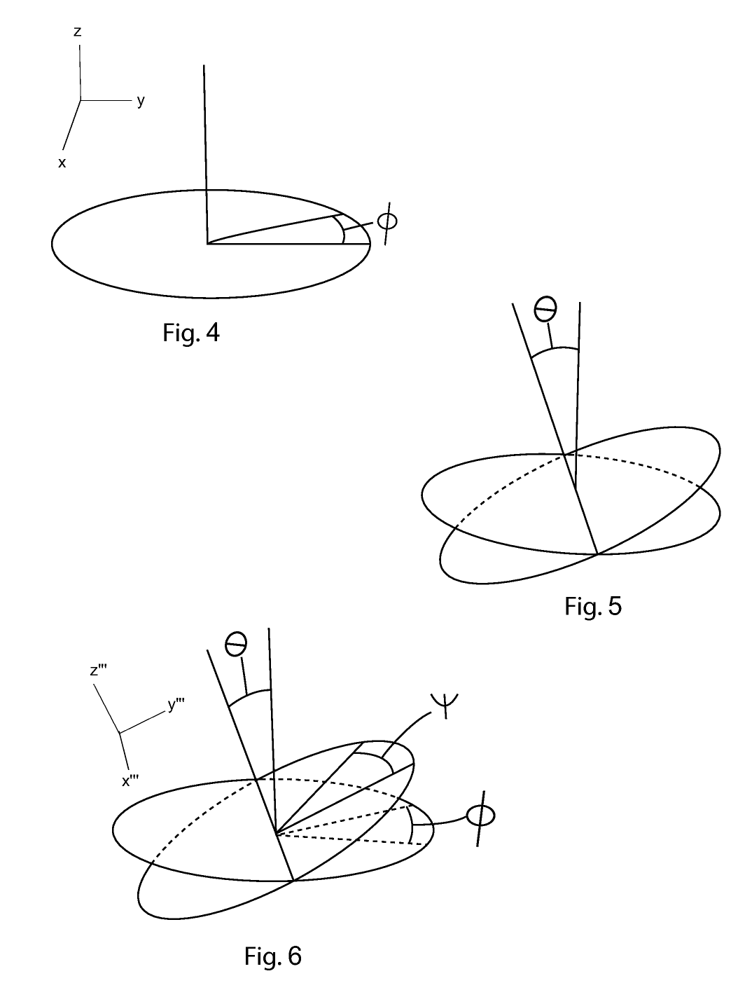

Another embodiment of the disclosed technology is shown in FIG. 3. The embodiment shown in FIG. 3 utilizes reflector 48 along the direction of propagation to create a resonant cavity. One example of reflector 48 is a Bragg reflector but the edge of the crystal substrate would also be useable or grooves etched into the material.

The disclosed SAW device 10 has a piezoelectric crystal substrate 12 formed from a material selected from the group of the LGX family of crystals, the substrate having a SAW propagation surface. Each individual device 10 operates at a distinct resonant frequency under unstrained isothermal conditions and over the range of strain and temperature in the environment. Strain is sensed and measured based on resonate frequency changes in the target SAW devices, which occurs as the object-of-interest (such as pistons, turbines blades, etc) transfers strain to the attached SAW sensor(s). A SAW temperature sensor of the disclosed technology, in proximity to the strain sensor may be incorporated, which is designed to be insensitive or respond differently to strain, and is used for determining the approximate strain sensor temperature as to allow strain sensor frequency measurement correction due to temperature variation. The frequency corrected signal is sampled periodically in time and further processed using spectral estimation techniques, such as time-windowed Fourier analysis, to determine mode parameters of the object-of-interest, such as resonant frequencies and respective amplitudes. This technique may also be used to monitor time varying changes in pressure. The zero-Hz spectral component is used to determine approximate static strain. Under the application where static strain measurement is not desired, temperature correction may not be required to get meaningful dynamic strain data of the object-of-interest.

The cut of a given piezoelectric crystal 12 is defined by Euler angles. A set of Euler angles is used to define the cut of a crystalline material 12 used to form the substrate of a SAW device 10 and the desired SAW propagation direction along the crystal surface. FIG. 4 shows an uncut LGX material referenced by three orthogonal principle axes labeled X, Y, and Z, while the surface 38 (FIG. 6) shows the cut LGX material forming the SAW substrate referenced by three orthogonal axes labeled X′″, Y′″, and Z′″. The elliptical surface 36 in FIG. 4 (containing axes X and Y) represents the orientation of the crystal within the uncut LGX material, while the tilted elliptical surface 38 (containing axes X′″ and Y′″) represents the orientation of the crystals within the cut of LGX material forming the substrate.

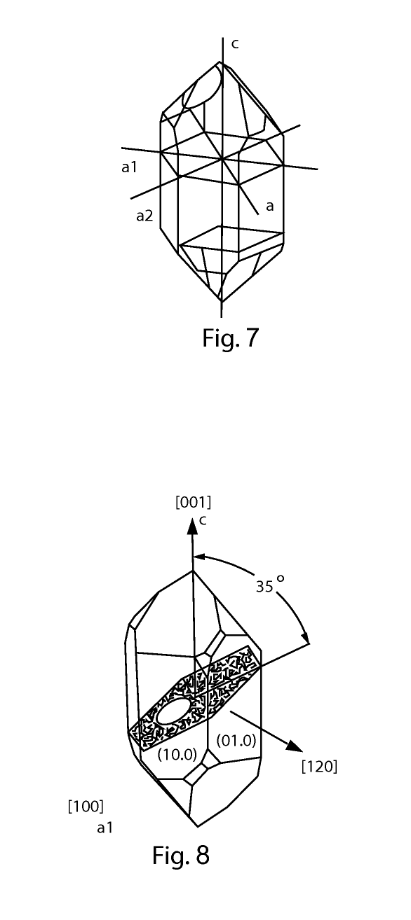

The spatial relationships between the two surfaces 36 and 38 are defined by first, second, and third Euler angles, designated by φ, θ, and ψ, respectively. The Euler angles represent rotations about the axes of the LGX material 36, to orient the axes, X′″, Y′″, and Z′″, of the cut crystal surface 38. According to convention, the cut surface 38 is considered as being rotated first about the +Z axis in a CCW fashion (Right Hand Rule) to offset the X′ axis from the X axis by Euler angle φ, as illustrated by FIG. 4, in which the other two axes are designated Y′ and Z′, following the first rotation. A second rotation then occurs around the +X′ axis in a CCW fashion by Euler angle θ to offset the Z″ axis from the Z′ axis, as illustrated in FIG. 5. In FIG. 5, the other two axes are designated X″ and Y″ following the second rotation. Finally, the crystal is rotated about the +Z″ axis in a CCW fashion to offset the X′″ axis from the X″ axis by Euler angle ψ, as shown in FIG. 6. In FIG. 6 the other two axes are designated Y′″ and Z′″ following the third rotation. Thus, rotated axis +Z′″ is perpendicular to the polished surface 38 of the cut LGX crystals. The desired propagation direction of transduced SAW energy within surface 38 is defined as the X′″ and X′″+180° directions for the forward and reverse propagating SAW waves respectively. FIG. 7 shows a quartz crystal with hexagonal crystallographic axes. FIG. 8 shows a possible cutting angle for the crystal shown in FIG. 7. As discussed above, based on the cut angle shown the wave propagation on the SAW sensor will have specific reactions to physical changes including strain, pressure and temperature.

Selecting a material and orientation for a given sensing application involves two primary considerations: (1) The substrate material itself. For high temperature applications the material must survive and retain its piezoelectricity at high temperatures. All LGX crystals operate at temperatures up to their melting points (˜1470° C. for LGS) without losing piezoelectric properties. (2) The piezoelectric coupling factor (k²). The k² factor measures the effectiveness of a piezoelectric material (with given cut and propagating direction) at converting electrical energy into mechanical energy, or vice versa. Orientations exhibiting a relatively high k² value for SAWs are sought for effectively exciting acoustic waves.

In addition, for devices to be used as temperature sensors, the temperature coefficient of delay (TCD) or temperature coefficient of frequency (TCF=−TCD) is a critical consideration. The TCD for a given orientation (usually given as ppm/° C.) defines the degree of change of the effective SAW velocity (corrected to include thermal expansion effect) induced by a small change in temperature.

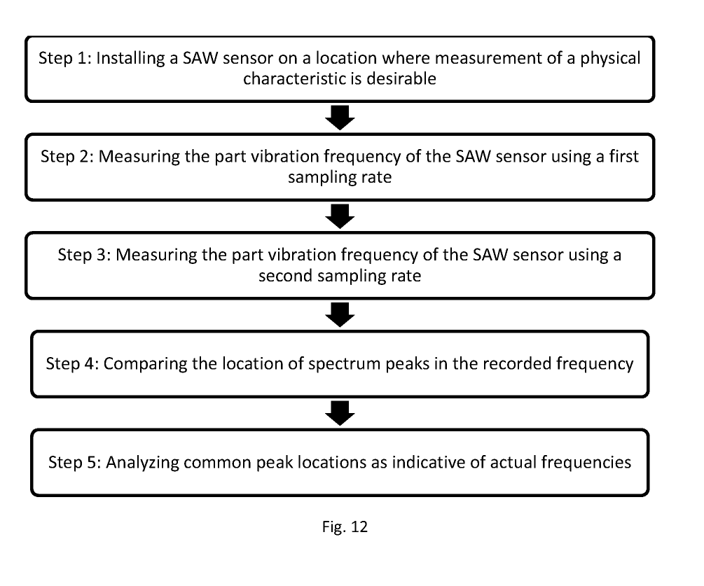

For the disclosed device, previously unidentified crystallographic orientations are disclosed FIG. 12, some of which present finite TCD below room temperature, and have the same TCD sign at high temperature (i.e. the turnover temperature is below room temperature). Orientations displaying the same TCD sign over a range from room-or-lower to high temperature have a single-valued frequency-to-temperature translation over said range. As the temperature of the disclosed device is increased above its turnover point, the thermal expansion coefficient (TCE) of the orientation along the propagation direction increasingly dominates the SAW temperature coefficient of velocity (TCV). As a result, device TCD at high temperature is positive since TCD=TCE−TCV.

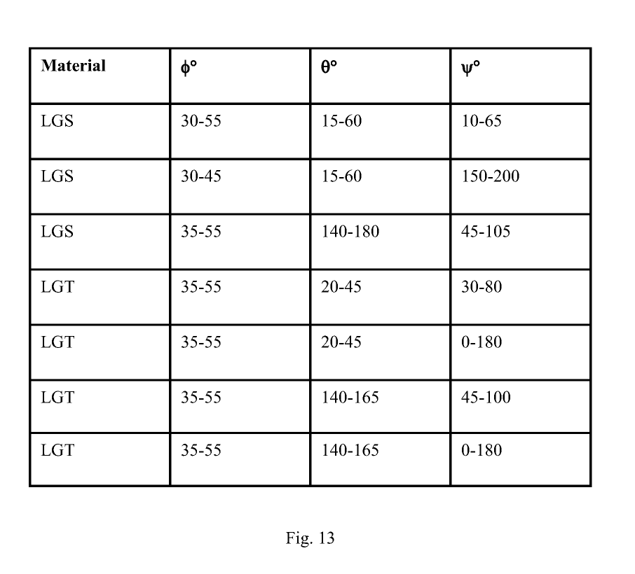

For the disclosed crystallographic orientations listed in FIG. 13, note that Euler angles <φ, θ, ψ> define a unique substrate orientation and propagation direction.

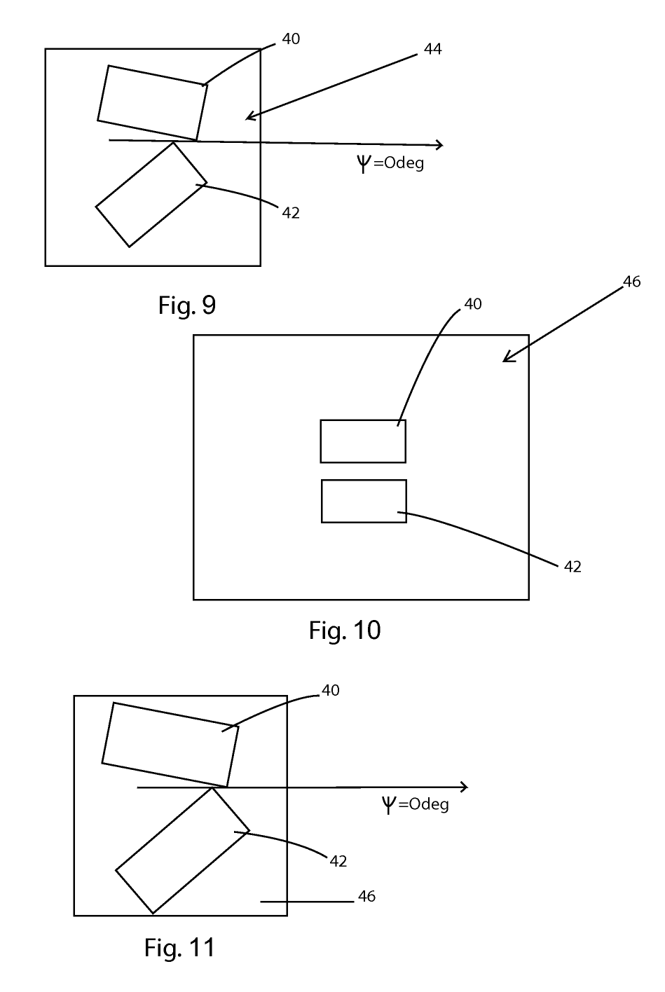

Another exemplary embodiment of the inventive concepts, shown in FIG. 9, is the use of two separate devices as a differential pair. Preferably, first SAW device 40 and second SAW device 42 are created on a single chip 44 that is made using a single wafer during processing. As shown the first SAW device 40 and second SAW device 42 are created at different orientations on the chip. The two separate devices have the same φ and θ Euler angles with a different ψ Euler angle defining the propagation direction along the surface. The resulting sensor pair can provide additional benefits including being less sensitive to drift and less sensitive to fabrication inconsistencies. As is the case with the other exemplary embodiments, this sensor pair can be used for many applications including temperature, pressure, and strain. While less desirable, it is also possible to create a sensor pair using devices created on separate wafers and then placed in close proximity. It is advantageous to create these using near identical φ and θ Euler angles. Identical φ and θ Euler angles are easier to achieve when using the same wafer to create both devices.

FIG. 10 shows another embodiment of the inventive concepts. In this embodiment two SAW sensors are attached to a part being tested. In this embodiment first SAW sensor 40 is rigidly attached to the part. In this way the first SAW sensor 40 will be sensitive temperature and to the strain of the part. Second SAW sensor 42 is not rigidly attached, or floating, to the part 46. In this way second SAW sensor 42 is not sensitive to the strain of the part as the strain is not transferred to the second SAW sensor 42. The use of a rigid attachment for first SAW sensor 40 and a non-rigid attachment for second SAW sensor 42 allows for a comparison of the two separate signals and thus elimination of the temperature affect on first SAW sensor 40 so that strain can be measured along with temperature. In this case, the output of first SAW sensor 40 will be a function of both strain and temperature and the output of second SAW sensor 42 will also be a function of temperature alone. This yields two equations and two unknowns, strain and temperature, allowing for calculation of both unknowns.

Alternatively, FIG. 11 shows another embodiment where each of first SAW sensor 40 and second SAW sensor 42 can be rigidly attached. Each SAW sensor will have a specific sensitivity to strain and temperature. As such, the output of first SAW sensor 40 will be a function of both strain and temperature and the output of second SAW sensor 42 will also be a function of both strain and temperature. This results in two separate equations and two separate unknowns. As was the case with one floating attachment, it is possible to calculate both the temperature and the strain of the part being measured.

FIG. 12 shows a method comprising 5 steps for measuring a physical parameter when the SAW device is under sampled. Step 1 is to install a SAW sensor on a location where measurement of a physical characteristic is desirable. The sensor could be located in many places including on a fan blade or inside a tube. Step 2 is measuring the part vibration frequency of the SAW sensor using a first sampling rate. Step 3 is measuring the part vibration frequency of the SAW sensor using a second sampling rate. The first and second sampling rates can be different and measured simultaneously by two separate ac-dc converters. Alternatively, the first sampling rate can be performed for a certain number of steps and then the second sampling rate can be performed by the same ac-dc converter. In the alternative, each sampling rate will be different. Step 4 is comparing the location of spectrum peaks in the recorded frequency. Step 5 is analyzing the common peak locations as indicative of actual frequencies. The use of unique sampling rates allows for actual peak locations to be determined.

We claim:

1. A wireless sensor for variable temperature environments, comprising:
a piezoelectric crystal substrate of the LGX family of crystals with a SAW propagation path defined by selected Euler angles between an uncut LGX material and a cut surface of LGX material;
a SAW sensor;
a power source for powering a SAW input transducer, wherein said input transducer is configured for receiving an RF interrogating signal; and
an antenna attached to said input transducer for receiving an RF interrogating signal from a signal processing system, with said sensor powered by said RF signal;
with said RF signal being converted to a SAW electromechanical signal via the input transducer for propagating within the crystal substrate
with said propagating signal being encoded to include information regarding states of sensor measurands
with said encoded signal being redetected by input transducer creating an encoded RF signal
with said encoded RF signal being retransmitted by said antenna to said signal processing system;
with said crystal being cut to selected Euler angles φ, θ, and ψ defining a selected crystal orientation and propagating direction.

2. The sensor of claim one wherein said SAW sensor further comprises:
a periodic interdigital transducer of several wavelength periodicities in width, said interdigital transducer, affixed to said piezoelectric crystal as a thin layer.

3. The sensor of claim one wherein said SAW sensor further comprises:
an input transducer;
a reflector located on both sides of said input transducer oriented to reflect SAW along the propagation direction.

4. A surface acoustic wave device comprising:
Piezoelectric crystal langasite and having a cut angle and SAW propagation direction represented by Euler angle expression (φ, θ, ψ) having values selected from one of the following groups:
Group 1: where φ is from 30 to 55°, where θ is from 15 to 60° and ψ is from 10 to 65°,
Group 2: where φ is from 30 to 45°, where θ is from 15 to 60° and ψ is from 150 to 200°,
Group 3: where φ is from 35 to 55°, where θ is from 140 to 180° and ψ is from 45 to 105°.

5. The SAW device of claim 4 in which said surface acoustic wave sensor is configured to generate a signal from an environment above 850° C.

6. The SAW device of claim 4 in which said surface acoustic wave sensor is configured to generate a signal from an environment below 850° C.

7. A surface acoustic wave device comprising:
Piezoelectric crystal langatate and having a cut angle and SAW propagation direction represented by Euler angle expression (φ, θ, ψ) having an φ value within the range of 35 to 55° with θ and ψ values selected from one of the following groups:
Group 1: where θ is from 20 to 45° and ψ is from 30 to 80°,
Group 2: where θ is from 140 to 165° and ψ is from 45 to 100°,
Group 3: where θ is from 20 to 45° and ψ is from 0 to 180°,
Group 4: where θ is from 140 to 165° and ψ is from 0 to 180°.

8. The SAW device of claim 7 in which said surface acoustic wave sensor is configured to generate a signal from an environment above 850° C.

9. The SAW device of claim 7 in which said surface acoustic wave sensor is configured to generate a signal from an environment below 850° C.

10. A wireless sensor comprising:
a first SAW device in accordance with claim 1 defined by Euler angles φ, θ, and ψ1;
a second SAW device in accordance with claim 1 defined by Euler angles φ, θ, and ψ2;
wherein ψ1 and ψ2 are different.

11. The sensor of claim 10 wherein said first SAW device and said second SAW device are made on a single wafer.

12. A SAW sensor comprising:
a first SAW device in accordance with claim 1 being rigidly affixed to a part being measured, said first SAW device affected by both strain to the part and temperature;
a second SAW device in accordance with claim 1, said second SAW device being attached in a non-rigid fashion so said second SAW device is only sensitive to temperature.

13. The sensor of claim 12 wherein:
said first SAW sensor in accordance is defined by Euler angles φ, θ, and ψ1;
said second SAW sensor is defined by Euler angles φ, θ, and ψ2;
wherein ψ1 and ψ2 are different.

14. The sensor of claim 12 wherein said second SAW device is rigidly attached.

15. A method of using the sensor in claim 1 for measuring the frequency characteristics of a dynamic measurand comprising:
a. installing a SAW sensor on a location where measurement of a physical characteristic is desirable;
b. measuring the dynamic measurand using a first sampling rate;
c. measuring the dynamic measurand using a second sampling rate;
d. calculating the spectrum of the time sampled dynamic measurand signals;
e. comparing the location of spectrum peaks;
f. analyzing common peak locations as indicative of actual frequencies.

16. The method of claim 15 wherein said first sampling rate is performed by a first ac-dc converter and said second sampling rate is performed simultaneously by a second ac-dc converter.

17. The method of claim 15 wherein said first sampling rate is performed by an ac-dc converter for a specified number of times then performing said second sampling rate by the same ac-dc convertor for the same number of times.
